(19) United States
(12) Patent Application Publication
(10) Pub. No.: US 2023/0219191 A1
(43) Pub. Date: Jul. 13, 2023

(54) POLISHING PAD, CHEMICAL MECHANICAL POLISHING APPARATUS INCLUDING THE SAME, AND METHOD FOR MANUFACTURING SEMICONDUCTOR DEVICE USING THE SAME

(71) Applicant: SAMSUNG ELECTRONICS CO., LTD., SUWON-SI (KR)

(72) Inventors: Sanha KIM, Daejeon (KR); Ji Su KIM, Seoul (KR); Yeong Bong PARK, Yongin-si (KR); Hyun Jun RYU, Daejeon (KR); Myung-Ki HONG, Uiwang-si (KR); Byoung Ho KWON, Hwaseong-si (KR); Dong Geun KIM, Daejeon (KR); Ji-Hun JEONG, Daejeon (KR); Sukkyung KANG, Daejeon (KR)

(73) Assignee: Korea Advanced Institute of Science and Technology, Daejeon (KR)

(21) Appl. No.: 17/805,735

(22) Filed: Jun. 7, 2022

(30) Foreign Application Priority Data
Jan. 7, 2022 (KR) 10-2022-0002523

(51) Int. Cl. B24B 37/26; B24B 37/24; B24B 37/22

(52) U.S. Cl. CPC B24B 37/26; B24B 37/24; B24B 37/22

(57) ABSTRACT

The present disclosure provides a polishing pad and a method of manufacturing a semiconductor device using the same. The method includes disposing a target layer on a semiconductor substrate and performing a chemical mechanical polishing process on the target layer using a polishing pad including a plurality of polishing protrusions facing the target layer. Each of the polishing protrusions includes a protruding portion and a surface layer at least partially covering the protruding portion, wherein the protruding portion is more elastic than the surface layer, and wherein the surface layer is harder than the protruding portion.

### CROSS-REFERENCE TO RELATED APPLICATION

This U.S. non-provisional application claims priority under 35 USC § 119 to Korean Patent Application No. 10-2022-0002523 filed on Jan. 7, 2022 in the Korean Intellectual Property Office, the disclosure of which is incorporated by reference herein in its entirety.

### TECHNICAL FIELD

The present disclosure relates to a polishing pad, a chemical mechanical polishing apparatus including the same, and a method for manufacturing a semiconductor device using the same. More specifically, the present disclosure relates to a polishing pad including fine protruding portions, a chemical mechanical polishing apparatus including the same, and a method for manufacturing a semiconductor device using the same.

### DISCUSSION OF THE RELATED ART

Chemical mechanical polishing (CMP) processes are widely used in semiconductor device manufacturing as a planarization technique for removing steps between layers formed on a substrate. The chemical mechanical polishing process can efficiently planarize films formed on the substrate by injecting a polishing slurry including polishing particles into a space between the substrate and the polishing pad and rubbing the polishing pad against the substrate. The polishing pads may include several protrusions that contact the films during the polishing process.

In some cases, however, the protrusions are too hard, which causes surface imperfects and/or damage in the final semiconductor device.

### SUMMARY

An aspect of the present disclosure is to provide a semiconductor device with increased quality and productivity.

Another aspect of the present disclosure is to provide a polishing pad capable of achieving increased polishing rate and flatness. In order to increase polishing efficiency of the chemical mechanical polishing process, the polishing pad may include fine protruding portions of various patterns.

Still another aspect of the present disclosure is to provide a chemical mechanical polishing apparatus capable of achieving increased polishing rate and flatness.

Aspects according to the present disclosure are not limited to those mentioned above. Other aspects and advantages according to the present disclosure that are not mentioned may be understood based on following descriptions, and may be more clearly understood based on embodiments according to the present disclosure. Further, it will be easily understood that the aspects and advantages according to the present disclosure may be realized using means shown in the claims and combinations thereof.

According to an aspect of the present disclosure, a method for manufacturing a semiconductor device includes disposing a target layer on a semiconductor substrate and performing a chemical mechanical polishing process on the target layer using a polishing pad including a plurality of polishing protrusions facing the target layer, wherein each of the polishing protrusions includes a protruding portion and a surface layer at least partially covering the protruding portion, wherein the protruding portion is more elastic than the surface layer, and wherein the surface layer is harder than the protruding portion.

According to another aspect of the present disclosure, a polishing pad includes a base layer including a plurality of protruding portions and a surface layer at least partially covering the protruding portions, wherein the protruding portion is more elastic than the surface layer is, wherein the surface layer is harder than the protruding portion is.

According to still another aspect of the present disclosure, a chemical mechanical polishing apparatus includes a rotatable platen, a carrier head assembly provide place a wafer on the platen, a polishing pad disposed on the platen and including a plurality of polishing protrusions facing the wafer, and a slurry supply configured to supply a polishing slurry between the wafer and the polishing pad, wherein each of the polishing protrusions includes a protruding portion and a surface layer at least partially covering the protruding portion, wherein the protruding portion is more elastic than the surface layer, and wherein the surface layer is harder than the protruding portion.

### BRIEF DESCRIPTION OF DRAWINGS

The above and other aspects and features of the present disclosure will become more apparent by describing in detail exemplary embodiments thereof with reference to the attached drawings, in which:

FIG. 1 is a schematic perspective view that illustrates a chemical mechanical polishing apparatus including a polishing pad according to some embodiments.

FIG. 2 is a schematic partial cross-sectional view that illustrates the polishing pad of FIG. 1.

FIGS. 3A to 3C are various exemplary perspective views that illustrate polishing protrusions of a polishing pad according to some embodiments.

FIGS. 4 to 6 are partial enlarged views that illustrate an effect of a polishing pad according to some embodiments.

FIG. 7 is an exemplary flowchart that describes a method for manufacturing a semiconductor device according to some embodiments.

FIGS. 8 to 11 illustrate structures of intermediate steps in a method for manufacturing a semiconductor device according to some embodiments.

### DETAILED DESCRIPTION OF THE EMBODIMENTS

For simplicity and clarity of illustration, elements in the drawings are not necessarily drawn to scale. The same reference numbers in different drawings represent the same or similar elements, and as such perform similar functionality. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. To the extent that a description of an element has been omitted, it may be understood that the element is at least similar to corresponding elements that are described elsewhere in the specification. Examples of various embodiments are illustrated and described further below. It will be understood that the description herein is not intended to limit the claims to the specific embodiments described. On the contrary, it is intended to cover alternatives, modifications, and equivalents included within the spirit and scope of the present disclosure as defined by the appended claims.

A shape, a size, a ratio, an angle, a number, etc. of a component disclosed in the drawings for illustrating embodiments of the present disclosure are provided as examples, and the present disclosure is not limited thereto. Furthermore, in the following detailed description of the present disclosure, numerous specific details are set forth in order to provide a thorough understanding of the present disclosure. However, it will be understood that the present disclosure may be practiced without these specific details.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present between the two elements or layers.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is “directly disposed” “on” or “on a top” of another layer, film, region, plate, or the like, the former directly contacts the latter. In this case of being “directly disposed”, still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may be actually executed at the same time. Depending on a related function or operation, the consecutive blocks may be executed in a reverse sequence.

In descriptions of temporal relationships, for example, temporal precedent relationships between two events such as “after”, “subsequent to”, “before”, etc., another event may occur therebetween, unless “directly after”, “directly subsequent” or “directly before” is indicated. The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

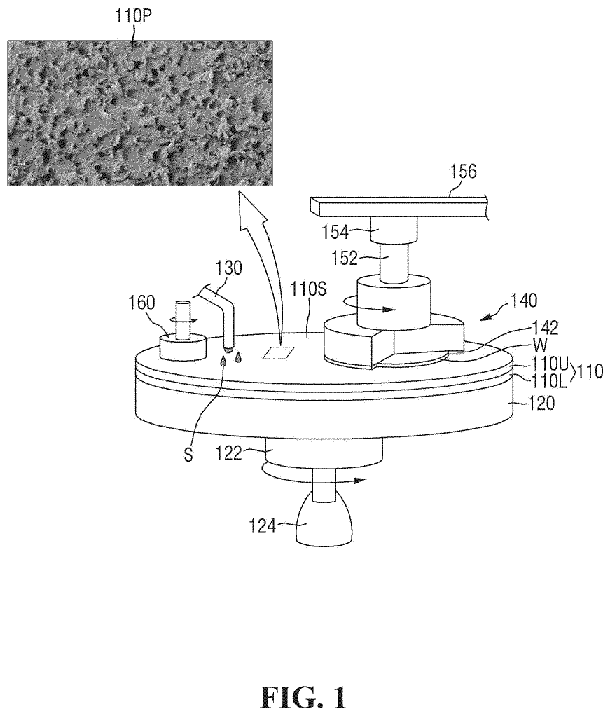

Hereinafter, a polishing apparatus and a chemical mechanical polishing apparatus including the same according to some embodiments will be described with reference to FIGS. 1 to 6. However, the following embodiments are merely examples, and the technical spirit of the present disclosure is not limited to those embodiments.

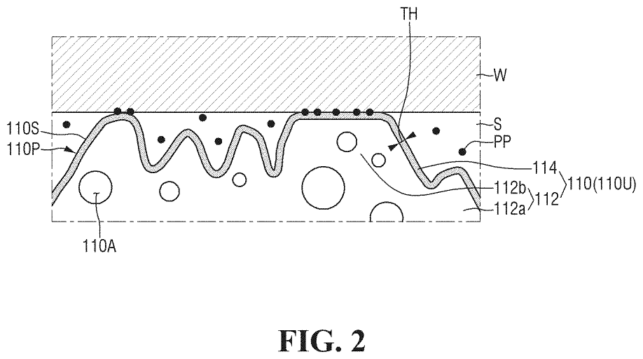

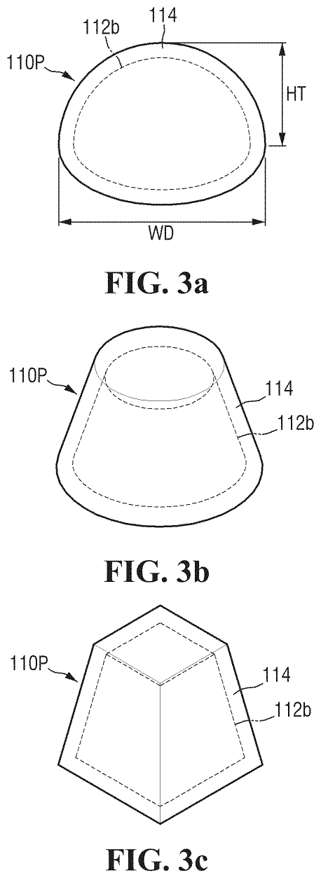

FIG. 1 is a schematic perspective view that illustrates a chemical mechanical polishing apparatus including a polishing pad according to some embodiments. FIG. 2 is a schematic partial cross-sectional view that illustrates the polishing pad of FIG. 1. FIGS. 3A to 3B are various exemplary perspective views that illustrate polishing protrusions of a polishing pad according to some embodiments.

Referring to FIG. 1, the chemical mechanical polishing apparatus according to some embodiments includes a polishing pad 110, a platen 120, a slurry supply 130, a carrier head assembly 140, and a pad conditioner 160.

The polishing pad 110 may be disposed on the platen 120. The polishing pad 110 may be embodied as a plate having a predetermined thickness, for example, a circular plate. However, the disclosure is not limited thereto. The polishing pad 110 may include a polishing surface 110S which faces a wafer W. The polishing surface 110S may have a plurality of polishing protrusions 110P, and thus have a predetermined roughness. While a chemical mechanical polishing process is being performed, the polishing surface 110S on which the polishing protrusions 110P are formed may contact the wafer W and polish the wafer W.

A shape and an arrangement of the polishing protrusions 110P shown in FIG. 1 are merely examples. The disclosure is not limited thereto. The shape, the arrangement, a size, the number, etc. of the polishing protrusions 110P may vary as needed. In one embodiment, the polishing pad 110 may include a plurality of polishing protrusions 110P that have a predetermined shape and are regularly arranged.

In some embodiments, the polishing pad 110 may include a support layer 110L and a polishing layer 110U. The polishing layer 110U may be supported on the support layer 110L. The polishing layer 110U may provide the polishing surface 110S on which the polishing protrusions 110P are formed. The polishing layer 110U may be in contact with the wafer W and polish the wafer W. The support layer 110L may support the polishing pad 110 so that the polishing pad 110 may be attached to the platen 120. The support layer 110L may include a material which is at least partially elastic for pressing the wafer W to be polished. For example, the support layer 110L may be softer than the polishing layer 110U may be. Thus, the support layer 110L may support the polishing layer 110U under a uniform elastic force with respect to the wafer W.

In some embodiments, the polishing pad 110 may further include a conductive material. A conductive version of the polishing pad 110 may be grounded to prevent a short circuit from occurring. In some other embodiments, the polishing pad 110 may be a non-conductor.

The platen 120 may be rotatable. The platen 120 may rotate the polishing pad 110 disposed on the platen 120. For example, a first driving shaft 122 connected to a bottom of the platen 120 may rotate upon receiving rotational power from a first motor 124. The platen 120 may rotate the polishing pad 110 about a rotation axis perpendicular to an upper surface of the platen 120.

The slurry supply 130 may be disposed adjacent to the polishing pad 110. While the chemical mechanical polishing process is being performed, the slurry supply 130 may supply a polishing slurry S on the polishing surface 110S of the polishing pad 110. Since the polishing surface 110S of the polishing pad 110 has the plurality of polishing protrusions 110P, the polishing slurry S may be smoothly supplied into between the wafer W and the polishing pad 110. For example, the polishing slurry S may fill spaces in between the plurality of polishing protrusions 110P.

The carrier head assembly 140 may be disposed adjacent to the polishing pad 110. The carrier head assembly 140 may supply the wafer W on the polishing surface 110S of the polishing pad 110. The carrier head assembly 140 may register and retain the wafer W on the polishing pad 110. The carrier head assembly 140 may independently control a polishing parameter (e.g., a pressure, etc.) related to one or more wafers W.

For example, the carrier head assembly 140 may include retaining ring 142 for retaining the wafer W under the flexible membrane. This carrier head assembly 140 may include a plurality of pressurized chambers which are defined by the flexible membrane and independently controlled. The pressurized chambers may apply an independently controllable pressure to a corresponding area on the flexible membrane or to a corresponding area on the wafer W.

The carrier head assembly 140 may be rotatable. The rotatable carrier head assembly 140 may rotate the wafer W affixed to the carrier head assembly 140. For example, a second driving shaft 152 connected to a top of the carrier head assembly 140 may rotate upon receiving rotational power from a second motor 154.

The carrier head assembly 140 may be supported on a support structure 156. The support structure 156 may be, for example, but not limited to, a carousel or a track. In some embodiments, the carrier head assembly 140 may translate laterally across an upper surface of the polishing pad 110. For example, the carrier head assembly 140 may vibrate on a slider of the support structure 156 or via rotational vibration of the support structure 156 itself.

FIG. 1 shows an embodiment in which only one carrier head assembly 140 is provided on the polishing pad 110. However, this is only an example. In another example, a plurality of carrier head assemblies 140 may be provided on the polishing pad 110 in order to increase space utilization of a surface area of the polishing pad 110. Further, in FIG. 1, it is illustrated that a rotation direction of the platen 120 and a rotation direction of the carrier head assembly 140 are identical to each other, but this is only an example. They may rotate in different rotation directions.

The pad conditioner 160 may be disposed adjacent to the polishing pad 110. The pad conditioner 160 may perform a conditioning process on the polishing surface 110S of the polishing pad 110. The pad conditioner 160 may stably maintain the polishing surface 110S of the polishing pad 110 so that the wafer W is effectively polished during the chemical mechanical polishing process.

Referring to FIG. 2, the polishing pad 110 may include a base layer 112 and a surface layer 114 which covers a surface of the base layer 112. The base layer 112 may include a plate 112a and a plurality of protruding portions 112b protruding from the plate 112a. For example, the polishing layer 110U of FIG. 1 may include the base layer 112 and the surface layer 114. The support layer 110L of FIG. 1 may support the plate 112a of the base layer 112.

The protruding portions 112b may be formed by, for example, patterning a top of the plate 112a. However, the disclosure is not limited thereto. The surface layer 114 may extend along surfaces of the protruding portions 112b. The surface layer 114 may be formed by, for example, coating or depositing a surface layer material on the base layer 112 on which the protruding portions 112b have been formed. For example, the surface layer 114 may be coated on the base layer 112 using a hot press process. Thus, the polishing surface 110S of the polishing pad 110 may be provided the plurality of polishing protrusions 110P including the protruding portions 112b and the surface layer 114 thereon.

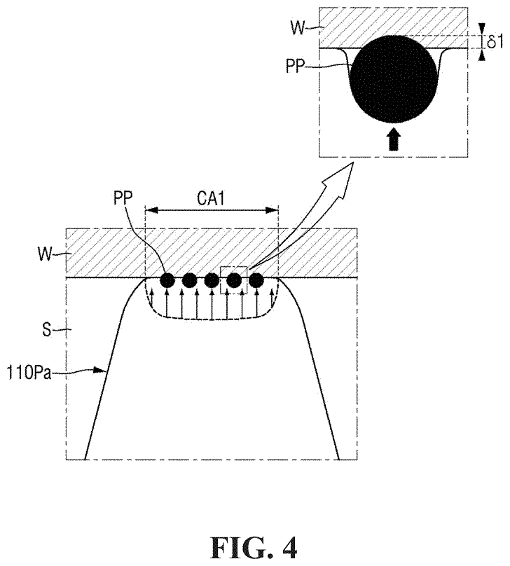

In each of the polishing protrusions 110P, the protruding portion 112b may be more elastic than the surface layer 114. For example, an elastic modulus of the protruding portion 112b may be greater than an elastic modulus of the surface layer 114. Further the surface layer 114 may be harder than each of the protruding portion 112bs. For example, a surface hardness (for example, a shore hardness) of the surface layer 114 may be greater than the surface hardness of the protruding portion 112b. As each polishing protrusion 110P includes the protruding portion 112b and the surface layer 114 having different physical properties, the polishing pad 110 may provide increased polishing rate and flatness. This will be described later in more detail in the description of FIGS. 4 to 6.

The physical properties of the base layer 112 and the physical properties of the surface layer 114 may be variously selected and used as needed. For example, the shore hardness of the base layer 112 may be in a range of about 10 Shore A to about 90 Shore D, and the surface layer 114 may be made of a material having the shore hardness greater than the shore hardness of the base layer 112. For example, the shore hardness of the base layer 112 may be in a range of about 20 Shore D to about 40 Shore D, and the shore hardness of the surface layer 114 may be in a range of about 30 Shore D to about 60 Shore D. However, this is merely one example and the disclosure is not limited thereto.

In some embodiments, the surface layer 114 may extend conformally along a profile of the surfaces of the protruding portions 112b. The surface layer 114 may constitute the polishing surface 110S of the polishing pad 110 which has a predetermined roughness. A thickness TH at which the surface layer 114 is formed may be about 0.1 μm to about 100 μm. When the thickness TH at which the surface layer 114 is formed is about 0.1 μm or smaller, the surface layer 114 may be easily worn and thus the polishing rate may be reduced. When the thickness TH at which the surface layer 114 is formed is about 100 μm or larger, an elasticity of the polishing protrusion 110P may be lowered, such that surface defects (e.g., scratches) may occur on the wafer W, and it may be difficult to control polishing selectivity. Accordingly, the thickness TH at which of the surface layer 114 is formed may be about 1 μm to about 10 μm.

In some embodiments, the base layer 112 may be made of a porous material including a plurality of pores 110A. In an example, the base layer 112 may include porous polyurethane. An average size (e.g., average particle diameter) of each of the pores 110A may be about 1 μm to about 50 μm. However, the disclosure is not limited thereto. A density of the pores 110A may be in a range of, for example, about 10% to about 60%. For example, this density may refer to a porosity. However, the disclosure is not limited to these ranges.

The protruding portion 112b and the surface layer 114 may constitute the polishing protrusion 110P, and may include a polymer having relatively high strength, flexibility and durability, and the like. For example, each of the base layer 112 and the surface layer 114 may include polyurethane, polyester, polyether, felt, epoxy, polyimide, polycarbonate, polyethylene, polypropylene, latex, nitrile-butadiene rubber (NBR), isoprene rubber, and/or combinations thereof. However, the disclosure is not limited thereto. In some embodiments, the base layer 112 may include polyurethane, polyether, felt, and/or combinations thereof such that the plurality of protruding portions 112b may be easily provided.

In an example, each of the base layer 112 and the surface layer 114 may include polyurethane. The polyurethane may be produced, for example, by mixing a curing agent with a polyurethane precursor obtained by a reaction between an isocyanate compound and a polyol compound.

The isocyanate compound may be an aliphatic isocyanate and/or an aromatic isocyanate. For example, the isocyanate compound may include a diisocyanate, for example, ethylene diisocyanate, hexamethylene diisocyanate, bis(isocyanatomethyl)cyclohexane, norbornane diisocyanate, isophorone diisocyanate, dicyclohexylmethane diisocyanate, toluene diisocyanate, naphthalene diisocyanate, phenylene diisocyanate, tolidine diisocyanate, 2,2′-diphenylmethane diisocyanate, 2,4′-diphenylmethane diisocyanate, 4,4′-diphenylmethane diisocyanate, xylene diisocyanate, and/or combinations thereof. However, the disclosure is not limited thereto.

The polyol compound may include, for example, polyether polyol, polyester polyol, polycarbonate polyol, polyester polycarbonate polyol, acrylic polyol, and/or combinations thereof. However, the disclosure is not limited thereto.

In some embodiments, the polyurethane precursor may be produced from a polyurethane precursor composition, and the polyurethane precursor composition may be a photo-curable polyurethane precursor composition or a heat-curable polyurethane precursor composition. The photo-curable polyurethane precursor composition may include a photo-curable polyurethane precursor. The photo-curable polyurethane precursor may include, for example, urethane methacrylate. However, the disclosure is not limited thereto. Urethane methacrylate may be prepared, for example, by polymerization of the isocyanate compound and the polyol compound and then adding methacrylate to the polymerization product.

The methacrylate compound may include, for example, 2-hydroxyethyl methacrylate, 2-hydroxypropyl methacrylate, 4-hydroxybutyl methacrylate, pentaerythritol trimethacrylate, and/or combinations thereof. However, the disclosure is not limited thereto.

The urethane methacrylate may have a structure in which one or two methacrylate groups (e.g., CH₂═CHC(═O)O—, or CH₂═C(CH₃)C(═O)O—) are present at an end of a core including a urethane moiety. The methacrylate group at the end of the core may be a crosslinkable functional group, and may act as a chemical crosslinking site.

The polyurethane precursor composition may further include a reaction initiator. The reaction initiator may include, for example, benzophenone, methylbenzophenone, chlorobenzophenone, acetophenone, benzyldimethylketal, diethylthioxanthone, diphenyl(2,4,6-trimethylbenzoyl)phosphine oxide, anthraquinone, and/or combinations thereof. However, the disclosure is not limited thereto.

The polyurethane precursor composition may optionally further include an organic solvent. The organic solvent may include, for example, ketone solvents such as acetone, methyl ethyl ketone, and/or methyl isobutyl ketone; cyclic ether solvents, such as tetrahydrofuran and dioxolane; ester solvents such as methyl acetate, ethyl acetate, and butyl acetate; aromatic solvents such as toluene and xylene; alicyclic solvents such as cyclohexane and methyl cyclohexane; alcohol solvents such as carbitol, cellosolve, methanol, isopropanol, butanol, and propylene glycol monomethyl ether; glycol ether solvents such as ethylene glycol monoethyl ether, ethylene glycol monobutyl ether, propylene glycol monomethyl ether, propylene glycol monopropylene ether, and combinations thereof. However, the disclosure is not limited thereto.

The curing agent may include, for example, an aliphatic amine compound, an aromatic amine compound, an aliphatic alcohol compound, an aromatic alcohol compound, and/or combinations thereof. However, the disclosure is not limited thereto.

In some embodiments, an inert gas may be supplied to the polyurethane precursor composition to produce the porous polyurethane. The inert gas may include, for example, nitrogen gas, argon gas, helium gas, and/or combinations thereof. However, the disclosure is not limited thereto. The inert gas may be uniformly supplied to a mixture of the polyurethane precursor and the curing agent. A size and density of the pores (e.g., 110A) of the porous polyurethane may be controlled based on a type of the inert gas, a supply flow rate thereof, and/or a supply pressure thereof.

The mixture of the polyurethane precursor and the curing agent may be injected into a predetermined mold and then may be cured therein. Thus, the polishing pad 110 in a solidified form according to a shape of the mold may be manufactured.

In some embodiments, the protruding portion (112b; or the base layer 112) may include first polyurethane, and the surface layer 114 may include second polyurethane having different physical properties from those of the first polyurethane. For example, an elastic modulus of the first polyurethane may be greater than that of the second polyurethane. Further, for example, a surface hardness (e.g., shore hardness) of the second polyurethane may be greater than a surface hardness of the first polyurethane. In an example, the first polyurethane may include polyether-based polyurethane, and the second polyurethane may include polyester-based polyurethane.

In some embodiments, the polishing slurry S may include a plurality of polishing particles PP. For example, the polishing slurry S may include a reactive agent (e.g., deionized water) in which the polishing particles PP are dispersed, and/or a chemical reaction catalyst. However, the disclosure is not limited thereto.

The polishing particle PP may function as an abrasive. For example, the polishing protrusions 110P of the polishing pad 110 may press the polishing particles PP against the wafer to polish the wafer W.

The polishing particle PP may include, for example, a metal oxide, a metal oxide coated with an organic or inorganic material, or a metal oxide in a colloidal state. For example, the polishing particle may include at least one of silica, alumina, ceria, titania, zirconia, magnesia, germania, mangania, and combinations thereof. However, the disclosure is not limited thereto.

A shape of the polishing particle PP may vary. The shape of the polishing particle PP may be, for example, a spherical shape, a square shape, a needle shape, or a plate shape.

An average size (e.g., average particle diameter) of the polishing particle PP may be about 10 nm to about 300 nm. When the size of the polishing particle PP is smaller than about 10 nm, the polishing rate of the wafer W may be reduced. When the size of the polishing particle PP is greater than about 300 nm, a surface defect (e.g., scratch) may occur on the wafer W, and it may be difficult to control the polishing selectivity.

In some embodiments, the polishing particles PP may include nanoparticles having an average size of about 100 nm or smaller. For example, the polishing particle PP may include, but is not limited to, a silica nanoparticle.

The polishing particles PP may include one size of particles. Alternatively, the polishing particles PP may have a combination of at least two sizes of particles. For example, the polishing particles PP may be controlled in a size thereof during a producing process such that the polishing particles have a particle size distribution in a bimodal form in which two sizes are mixed with each other. Alternatively, the polishing particles PP may have a particle size distribution in which three sizes are mixed with each other to exhibit three peaks. When polishing particles having a relatively large size and polishing particles having a relatively small size are mixed with each other, increased dispersibility may be obtained. Further, the polishing particles PP may reduce surface defects of the wafer W.

Referring to FIG. 3A to FIG. 3C, each polishing protrusion 110P may have various shapes.

In one example, as shown in FIG. 3A, some or all of the polishing protrusions 110P may have a hemisphere shape. For example, the protruding portion 112b protruding in the hemispherical shape may be formed, and the surface layer 114 may conformally extend along the surface of the protruding portion 112b.

In another example, as shown in FIG. 3B, some or all of the polishing protrusions 110P may have a truncated cone shape. For example, the protruding portion 112b protruding in the truncated cone shape may be formed, and the surface layer 114 may conformally extend along the surface of the protruding portion 112b.

In still another example, as shown in FIG. 3C, some or all of the polishing protrusions 110P may have a quadrangular pyramid shape. For example, the protruding portion 112b protruding in a quadrangular pyramid shape may be formed, and the surface layer 114 may conformally extend along the surface of the protruding portion 112b.

The shapes of each of the polishing protrusions 110P shown in each of FIGS. 3A to 3C are merely examples. Each of the polishing protrusions 110P may have other various shapes protruding from the surface of the polishing pad 110.

In some embodiments, a diameter (e.g., WD of FIG. 3A) of each of the polishing protrusions 110P may be about 1 μm to about 1,000 μm. When the diameter of each of the polishing protrusions 110P is smaller than about 1 μm, the polishing rate may be reduced. When the diameter of each of the polishing protrusions 110P is greater than about 1,000 μm, a surface defect (e.g., a scratch) may occur in the polishing target layer, and it may be difficult to adjust the polishing selectivity.

In some embodiments, a height (e.g., HT in FIG. 3A) of each polishing protrusion 110P may be about 10 μm to about 1,000 μm. The height may refer to a length of each polishing protrusion 110P in a vertical dimension, where the vertical dimension is a normal direction from the plane of the polishing pad 110. In some embodiments, the height may be with respect to an average level of a polishing surface of the polishing pad 110; in other embodiments, the height may be with respect to the lowest level of the polishing surface (e.g., the deepest trench). When the height of each of the polishing protrusions 110P is smaller than about 10 μm, the polishing rate may be reduced. When the height of each of the polishing protrusions 110P is greater than about 1,000 μm, a surface defect (e.g., a scratch) may occur in the polishing target layer, and it may be difficult to control the polishing selectivity.

FIGS. 4 to 6 are partial enlarged views that illustrate an effect of a polishing pad according to some embodiments. For convenience of illustration, duplicate description of components with reference to FIGS. 1 to 3C may be omitted.

In general, since a soft material has a relatively high elasticity and a hard material has a relatively low elasticity, it is difficult to simultaneously achieve a high polishing rate and a high flatness using a polishing protrusion made of a single material.

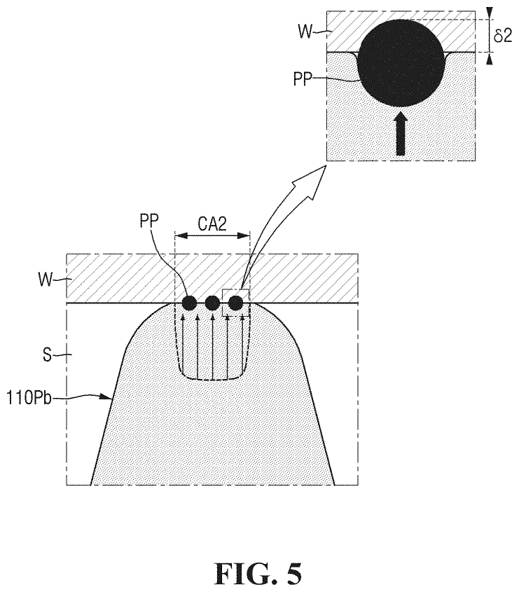

For example, referring to FIGS. 4 and 5, a first polishing protrusion 110Pa including a relatively soft material and a second polishing protrusion 110Pb including a relatively hard material may be provided. The first polishing protrusion 110Pa and the second polishing protrusion 110Pb may each press the polishing particles PP of the polishing slurry S against the wafer to polish the wafer W.

In this example, the first polishing protrusion 110Pa is softer than the second polishing protrusion 110Pb, such that a first pressing depth δ1 by which the first polishing protrusion 110Pa presses the polishing particles PP into the wafer W is less than a second pressing depth δ2 by which the second polishing protrusion 110Pb presses the polishing particles PP into the wafer W. Since the polishing rate of the wafer is proportional to the depth by which the polishing particles PP are pressed into the wafer, the first polishing protrusion 110Pa including only the relatively soft material may cause a low polishing rate.

On the contrary, since the second polishing protrusion 110Pb is harder than the first polishing protrusion 110Pa in this example, the second polishing protrusion 110Pb may achieve a relatively high polishing rate. However, since the second polishing protrusion 110Pb has the lower elasticity than that of the first polishing protrusion 110Pa, a second contact area CA2 between the second polishing protrusion 110Pb and the wafer W may be smaller than a first contact area CA1 between the first polishing protrusion 110Pa and the wafer W. Since a force applied to the wafer W is inversely proportional to a contact area between the polishing protrusion and the wafer, the second polishing protrusion 110Pb in contact with the wafer W by a relatively smaller area may apply a strong force to the wafer W to compensate, which can result in the formation of a surface defect (for example, scratch). Accordingly, the second polishing protrusion 110Pb including only a relatively hard material has a problem of decreased flatness.

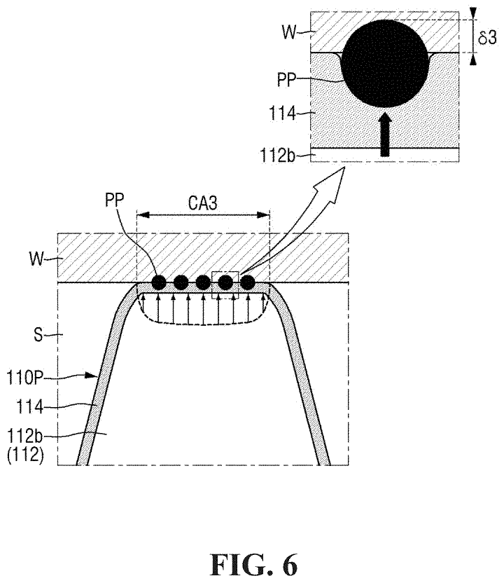

By way of contrast, referring to FIG. 6, the polishing protrusion 110P of the polishing pad according to some embodiments of the present disclosure includes the protruding portion 112b and the surface layer 114 with different physical properties from each other, so that the polishing rate and the flatness of the chemical mechanical polishing process may be increased at the same time.

Specifically, the polishing protrusion 110P may press the polishing particles PP with a relatively strong force using the relatively hard surface layer 114. For example, a third pressing depth δ3 by which the polishing protrusion 110P presses the polishing particles PP into the wafer W may be greater than the first pressing depth (δ1 in FIG. 4) by which the first polishing protrusion 110Pa presses the polishing particles PP into the wafer W. Accordingly, the polishing protrusion 110P may provide an increased polishing rate, compared to the first polishing protrusion 110Pa. In some examples, the third pressing depth δ3 may be less than the second pressing depth δ2, which may prevent scratches, thereby providing increased flatness.

Further, since each polishing protrusion 110P uses the relatively soft protruding portion 112b as a base, the polishing protrusion 110P may contact the wafer W by a relatively large area. For example, a third contact area CA3 by which the polishing protrusion 110P contacts the wafer W may be larger than the second contact area (CA2 in FIG. 5) by which the second polishing protrusion 110Pb contacts the wafer W. Accordingly, the polishing protrusion 110P may prevent the surface defects (e.g., scratches) of the wafer W to provide increased flatness compared to the second polishing protrusion 110Pb.

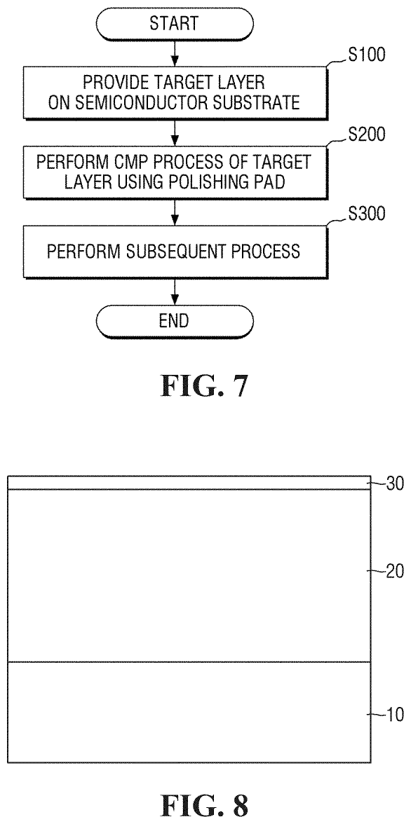

Hereinafter, a method for manufacturing a semiconductor device according to exemplary embodiments will be described with reference to FIGS. 7 to 11. However, these embodiments are provided as mere examples, and the technical spirit of the present disclosure is not limited to these embodiments. For convenience of illustration, duplicate description of components described above using FIGS. 1 to 6 will be briefly described or omitted.

FIG. 7 is a flowchart that describes a method for manufacturing a semiconductor device according to some embodiments. FIGS. 8 to 11 illustrate structures of intermediate steps in a method for manufacturing a semiconductor device according to some embodiments. For example, the method described with reference to FIGS. 7 to 10 may use the chemical mechanical polishing apparatus described above.

Referring to FIGS. 7 to 10, a target film 40 is provided on the semiconductor substrate 10 in 5100.

For example, as shown in FIG. 8, an interlayer insulating layer 20 and an inserted layer 30 may be sequentially formed on the semiconductor substrate 10.

The semiconductor substrate 10 may be made of a bulk silicon or silicon-on-insulator (SOI). Alternatively, the semiconductor substrate 10 may be embodied as a silicon substrate, or may be a substrate including a material other than silicon, such as silicon germanium, silicon germanium on insulator (SGOI), indium antimonide, lead tellurium compound, indium arsenide, indium phosphide, gallium arsenide. or gallium antimonide. However, the disclosure is not limited thereto. For convenience of description, an example in which the semiconductor substrate 10 is embodied as the silicon substrate will be described below.

The interlayer insulating layer 20 may be deposited on the semiconductor substrate 10. The interlayer insulating film 20 may include, for example, at least one of silicon oxide, silicon nitride, silicon oxynitride, and combinations thereof. However, the disclosure is not limited thereto.

The inserted layer 30 may be deposited on the interlayer insulating layer 20. The inserted layer 30 may function as an etch stop layer in a chemical mechanical polishing process to be described later.

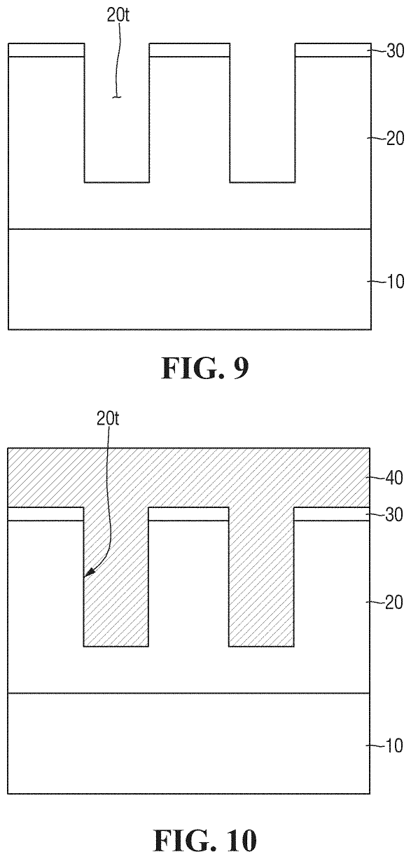

A shown in FIG. 9, a trench 20t may be formed in the interlayer insulating layer 20 and the inserted layer 30. The trench 20t may be formed by etching a portion of the interlayer insulating layer 20 and a portion of the inserted layer 30. In some embodiments, the trench 20t may have a width of about 10 nm or less.

A shown in FIG. 10, a target layer 40 may be formed on the interlayer insulating layer 20 and the inserted layer 30. The target layer 40 may be formed to fill the trench 20t.

The target layer 40 may include a semiconductor material, a conductive material, an insulating material, or a combination thereof. For example, the target layer 40 may include a semiconductor material such as polysilicon and/or an epitaxial layer. In another example, the target layer 40 may include a conductive material such as doped polysilicon, metal, metal silicide, and/or metal nitride. In still another example, the target layer 40 may include an insulating material such as silicon oxide, silicon nitride, silicon oxynitride, a low-k material having a dielectric constant lower than that of silicon oxide, and/or a high-k material having a higher dielectric constant than that of silicon oxide.

Although it is illustrated that the target layer 40 is formed of a single layer, this is only to provide an example. In some embodiments, the target layer 40 may be formed of a multilayer in which a plurality of layers are stacked. In one example, the target layer 40 may include a stack of a plurality of insulating layers, and may include a conductive layer or a semiconductor layer interposed between adjacent ones of the stacked insulating layers.

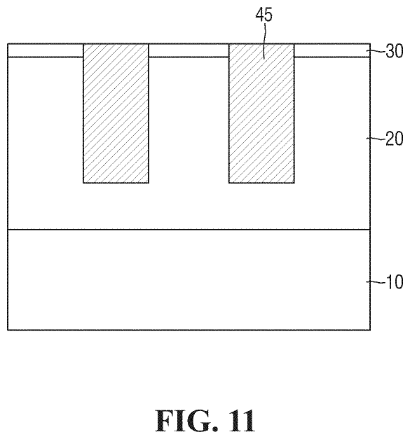

Referring to FIG. 7, FIG. 10, and FIG. 11, a chemical mechanical polishing process is performed on the target film 40 in S200.

The chemical mechanical polishing process on the target layer 40 may be performed using the polishing pad according to some embodiments. For example, the polishing pad 110 as described above using FIGS. 1 to 6 may be used. The polishing slurry S may be provided into between the semiconductor substrate 10 on which the target layer 40 has been formed and the polishing pad 110. The target layer 40 may rotate while being in contact with the polishing pad 110. For example, the target layer 40 may be rotated by the chemical mechanical polishing apparatus. When using the polishing pad according to some embodiments, the chemical mechanical polishing process may achieve an increased polishing rate and increased flatness.

The chemical mechanical polishing process may be performed, for example, until the inserted layer 30 is exposed. Thus, a target pattern 45 filling the trench 20t may be formed.

Then, referring to FIG. 7, a subsequent process may be performed in S300.

The subsequent process may include various semiconductor processes on the semiconductor substrate 10 and/or the target pattern 45. For example, the semiconductor processes may include, but are not limited to, a deposition process, an etching process, an ion process, and a cleaning process. The semiconductor processes may include a test process on a semiconductor device at a wafer level. As the subsequent process is performed, various integrated circuits and wirings required for the semiconductor device may be formed.

When semiconductor chips are formed on the semiconductor substrate 10 via the semiconductor processes, each of the semiconductor chips may be individualized. The individualization of each of the semiconductor chips may be performed via a sawing or cutting process using a blade or a laser. Subsequently, a packaging process on each of the semiconductor chips may be performed. The packaging process may refer to a process of mounting each semiconductor chip on a circuit board (e.g., a printed circuit board (PCB)) and sealing the semiconductor chip using a sealing material. Further, the packaging process may include stacking a plurality of semiconductor chips in multiple layers on the circuit board to form a stack package, or stacking a stack package on another stack package to form a POP (Package On Package) structure. A semiconductor package may be formed via a packaging process on each of the semiconductor chips. The semiconductor processes may include a test process on a semiconductor device at a package level.

While the present inventive concept has been particularly shown and described with reference to embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, and that reference is made to the appended claims rather than the foregoing description to indicate the scope of the invention.

What is claimed is:

1. A method for manufacturing a semiconductor device, the method comprising:
disposing a target layer on a semiconductor substrate; and
performing a chemical mechanical polishing process on the target layer using a polishing pad including a plurality of polishing protrusions facing the target layer,
wherein each of the polishing protrusions includes a protruding portion and a surface layer at least partially covering the protruding portion,
wherein the protruding portion is more elastic than the surface layer, and
wherein the surface layer is harder than the protruding portion.

2. The method of claim 1, wherein an elastic modulus of the protruding portion is greater than an elastic modulus of the surface layer, and
wherein a surface hardness of the surface layer is greater than a surface hardness of the protruding portion.

3. The method of claim 1, wherein performing the chemical mechanical polishing process includes using a polishing slurry containing a plurality of polishing particles.

4. The method of claim 3, wherein a diameter of each of the polishing particles is 100 nm or smaller.

5. A polishing pad comprising:
a base layer including a plurality of protruding portions; and
a surface layer at least partially covering the protruding portions,
wherein the protruding portion is more elastic than the surface layer, and
wherein the surface layer is harder than the protruding portion.

6. The polishing pad of claim 5, wherein an elastic modulus of the protruding portion is greater than an elastic modulus of the surface layer.

7. The polishing pad of claim 5, wherein a shore hardness of the surface layer is greater than a shore hardness of the protruding portion.

8. The polishing pad of claim 5, wherein the surface layer extends conformally along a surface of the base layer.

9. The polishing pad of claim 5, wherein the protruding portion includes first polyurethane, and the surface layer includes second polyurethane, wherein the second polyurethane is harder than the first polyurethane.

10. The polishing pad of claim 9, wherein the first polyurethane includes polyether-based polyurethane, and
wherein the second polyurethane includes polyester-based polyurethane.

11. The polishing pad of claim 5, wherein the base layer includes a plurality of pores.

12. The polishing pad of claim 5, wherein the polishing pad further comprises a support layer to support the base layer, and
wherein the support layer is softer than the base layer is.

13. The polishing pad of claim 5, wherein each of the protruding portions is hemispherical.

14. The polishing pad of claim 5, wherein the surface layer has a thickness in a range of 0.1 μm to 100 μm.

15. The polishing pad of claim 5, wherein the plurality of protruding portions and the surface layer form a plurality of polishing protrusions, and
wherein a diameter of each of the polishing protrusions is in a range of 1 μm to 1,000 μm.

16. The polishing pad of claim 5, wherein the plurality of protruding portions and the surface layer form a plurality of polishing protrusions, and
wherein a vertical dimension of each of the polishing protrusions is in a range of 10 μm to 1,000 μm.

17. A chemical mechanical polishing apparatus comprising:
a rotatable platen;
a carrier head assembly provide place a wafer on the platen;
a polishing pad disposed on the platen and including a plurality of polishing protrusions facing the wafer; and
a slurry supply configured to supply a polishing slurry between the wafer and the polishing pad,
wherein each of the polishing protrusions includes a protruding portion and a surface layer at least partially covering the protruding portion,
wherein the protruding portion is more elastic than the surface layer, and
wherein the surface layer is harder than the protruding portion.

18. The apparatus of claim 17, wherein an elastic modulus of the protruding portion is greater than an elastic modulus of the surface layer, and
wherein a surface hardness of the surface layer is greater than a surface hardness of the protruding portion.

19. The apparatus of claim 17, wherein the polishing slurry includes a plurality of polishing particles.

20. The apparatus of claim 19, wherein a diameter of each of the polishing particles is 100 nm or smaller.
